(19) United States
(12) Patent Application Publication
(10) Pub. No.: US 2026/0126827 A1
(43) Pub. Date: May 7, 2026

(54) ADJUSTED-FREQUENCY SYNCHRONIZER FOR CLOCK DOMAIN CROSSING

(71) Applicant: STMicroelectronics International N.V., Geneva (CH)

(72) Inventors: Jerome LACAN, Trets (FR); Christophe EVA, Rousset (FR)

(73) Assignee: STMicroelectronics International N.V., Geneva (CH)

(21) Appl. No.: 19/369,017

(22) Filed: Oct. 24, 2025

(30) Foreign Application Priority Data
Nov. 4, 2024 (FR) FR2412052

(51) Int. Cl. G06F 1/12; G06F 1/08; H03K 3/037; H03K 23/50

(52) U.S. Cl. CPC G06F 1/12; G06F 1/08; H03K 3/037; H03K 23/50

(57) ABSTRACT

A synchronizer with flip-flops has a reduced number of flip-flops coupled in series, receiving as an input data of a first clock domain and supplying as an output data in the second clock domain. The second clock signal is at a variable frequency adjusted to a target frequency, by a division factor. The flip-flops are timed by a clock signal subsampling the second clock signal by a factor k1. The subsampled clock signal is generated by a frequency divider propagating a pulse of the signal every k1 clock pulses, while keeping the edges aligned.

### BACKGROUND

### Technical Field

Embodiments and implementations relate to the field of synchronizing data in systems having asynchronous time domains.

### Description of the Related Art

A digital system is often composed of several digital subsystems. When these digital subsystems operate synchronously with the same clock, synchronizing the signals circulating between these digital subsystems is not necessary. On the other hand, if these digital subsystems are asynchronous, i.e., operating with clocks that are asynchronous at least in phase, the signals circulating between these digital subsystems must be synchronized. For example, a computer system may operate at a given frequency whereas the processor may operate at another frequency.

An interface circuit that enables data to be transferred from one clock domain to another is called a synchronization unit or “synchronizer.”

FIG. 1 illustrates a synchronizer with flip-flops 100 according to the prior art for synchronizing a data signal SIG_1. The flip-flop A 105 operates in the original clock domain A 107. The set of flip-flops B operates in the target clock domain B 114.

In a known manner, a flip-flop is a logic circuit using an operator between its inputs and maintaining the values of its output or outputs-evaluated at a clock edge-during the clock cycle.

The clock domain A 107 and the clock domain B 114 are asynchronous clock domains. The flip-flop A 105 receives the input signal SIG_1 at the data input “d” and is timed at a first clock frequency f_{A}, by the first clock signal CLK_A at the clock input. FIG. 1 illustrates a set of four flip-flops B1 110, B2 111, B3 112 and B4 113 operating in series or “cascade” (the output “q” of the previous flip-flop supplying the input “d” of the following one). Another number of flip-flops can be envisaged. In particular, synchronizers with two flip-flops B are widely known.

The input signal SIG_1 is transferred to the output “q” of the flip-flop A 105 by the action of the first clock signal CLK_A. The flip-flops of the set B are timed at a second clock frequency f_{B}, by the second clock signal CLK_B, and the output signal at the output “q” of the flip-flop A 105 is transferred in series via each of the flip-flops in the set B as far as the final output “q” at the output node 120.

If a clock source (for example f_{B}) has a maximum operation frequency (f_{Bmax}), it can however be of variable frequency in the case where a user can adjust the frequency of the domain through a clock divider integrated in the clock source.

FIG. 2 illustrates a time diagram 200 of the signals of the synchronizer 100. The following are shown: the signal A_q 205 at the output of the flip-flop A 105, i.e., at the input of the target clock domain B 114—, the clock signal CLK_B 207 of the target clock domain B 114, the signal B1_q 210 at the output of the first flip-flop B1 110, the signal B2_q 211 at the output of the following flip-flop B2 111, the signal B3_q 212 at the output of the again following flip-flop B3 112 and the signal B4_q 213 at the output of the last flip-flop B4 114. The signal B4_q corresponds here to the output signal OUTPUT 120. Each output signal Bi_q of an intermediate flip-flop Bi corresponds to the input signal B(i+1)_d of the following intermediate flip-flop B(i+1).

There is a probability that, during the sampling of the signal A_q by the flip-flop B1 110 in the target clock domain 114, the output B1_q of the flip-flop B1 may go into a metastable state. This probability—which decreases over time—is illustrated symbolically by the shading after each edge. The following flip-flop B2 will have a smaller probability of doing the same (illustrated symbolically by the shading), and so on.

These risks of metastable state depend on the parameters of the flip-flops and on the target frequency f_{B} of the clock CLK_B. Putting the four flip-flops in series reduces this risk of metastable state at the output 120, at the cost of an offset sampling of a number of clock cycles corresponding to the number of additional flip-flops (for example with respect to a synchronizer with two flip-flops). The number N_{sync} of flip-flops B to be used is generally determined by the following formula:

$$MTBF = \frac{{e}^{t / {t}_{r}}}{N \cdot {f}_{A} \cdot {f}_{B} \cdot {T}_{w}}$$

where t, the resolution time, is equal to

$$t = ( {N}_{sync} - 1 ) \cdot ( \frac{1}{{f}_{B}} - {T}_{setip} - {T}_{cp \to q} - {T}_{uncertainty} )$$

MTBF is the mean time between failures.

tᵣ (resolution time of a flip-flop), T_{W} (metastability window), N (total number of flip-flops in the synchronizer or synchronization system), Tₛₑₜᵤₚ (duration of flip-flop setup), T_{cp→q} (latency time CP—clock pulse—at Q—output—of a flip-flop), T_{uncertainty} (constant) are fixed parameters, related to the flip-flops and/or to the circuit design selected.

A greater number N_{sync} of flip-flops is prejudicial to the compactness of the synchronizer 100, as well as to the electrical consumption thereof. It also delays the conversion of the input signal SIG_1 in the target clock domain.

To contain this number, it is necessary to improve the performances of the flip-flops, which has a cost.

Furthermore, the search for enhanced performances of the clock domain B 114 is generally accompanied by an increase in the frequency f_{B}, and thereby an ever greater number of flip-flops for a maintained MBTF. By way of example, the frequency f_{B} may range from a few tens of MHz (for example 10 to 50 MHz) to several hundreds of MHz (for example 400 MHz).

### BRIEF SUMMARY

It would be beneficial to improve the synchronizers between asynchronous clock domains to overcome the aforementioned drawbacks. In one embodiment, the multiple flip-flops put in series reduce the risks of metastable state by extending the sampling time of a number of clock cycles corresponding to the number of additional flip-flops. Thus all or some of the intermediate flip-flops can appear superfluous provided that the sampling time is kept.

In this light, one embodiment includes a unit for synchronizing between a first clock domain timed by a first clock signal and a second clock domain asynchronous with the first clock domain and timed by a second clock signal, the synchronization unit including:
a set of flip-flops put in series, receiving as an input data of the first clock domain and supplying as an output data in the second clock domain (i.e., the first flip-flop receiving the input, the last flip-flop delivering the output),
wherein the second clock signal is at a variable frequency adjusted to a target frequency to supply a clock signal timing the flip-flops and/or the flip-flops are timed by a clock signal subsampling the second clock signal.

Two mechanisms, optionally combinable, make it possible to adjust the period between two rising (or falling) edges to the number of flip-flops used. By adjusting, generally downwards, the clock frequency used by the flip-flops of the synchronization unit, the number of flip-flops can be reduced. Thus the synchronization unit can be compact and economical in electrical consumption.

A variable-frequency clock source typically includes a clock divider for adjusting the output frequency by an integer factor k0 (of the maximum operational frequency). The clock period is therefore multiplied by k0. The frequency of the second clock signal can thus be adjusted to the number of flip-flops used.

In one embodiment, “Subsampling” is a process that reduces the frequency of the clock signal by an integer factor “k1” greater than 1. The clock period is therefore multiplied by k1. In concrete terms, clock cycles (or pulses) are eliminated from the clock signal. The clock and subsampled-clock signals remain in phase, meaning that the rising (or falling) clock edges kept are aligned with those of the initial clock signal (the second clock signal).

Moreover, by fixing the division factor k0 and/or subsampling factor k1, it is possible to obtain a substantial reduction in the number of flip-flops, typically to only two units.

It is also possible, through the selection of the factor or factors k0 and k1, to compensate for other parameters of the above formula, typically the parameters of the flip-flops. Thus it is once again possible to use any type of flip-flop, including lower-grade ones, and therefore not to have difficulty in developing novel types of higher-grade component.

One embodiment includes a method for synchronization between a first clock domain timed by a first clock signal and a second clock domain asynchronous with the first clock domain and timed by a second clock signal, the method including the following steps:
obtaining at least one clock-division or clock-subsampling factor,
adjusting, by means of the clock-division factor, a variable frequency of the second clock signal at a target frequency to supply a clock signal timing the flip-flops and/or generating, by means of the clock-subsampling factor obtained, a clock signal subsampling the second clock signal, and
controlling, with the adjusted and/or generated clock signal, flip-flops put in series in a synchronization unit that receives as an input data of the first clock domain and supplies as an output data in the second clock domain.

An electronic signal including a synchronization unit as defined in the present disclosure is also proposed.

Features of some embodiments are defined below with reference to the device, while they can be transposed into method features.

In one embodiment, the synchronization unit includes a subsampler (or subsampling unit) configured to subsample an input signal by a subsampling factor k1, an integer greater than or equal to 2, the subsampler receiving, as input signal, the second clock signal.

In one embodiment, the synchronization unit includes a user interface for allowing a configuration of the subsampling factor k by a user. The user can thus easily adjust or tune a synchronization-unit design (comprising for example two flip-flops) to a variable target frequency f_{b} and/or to flip-flops of all types.

In one embodiment, a source of the second clock signal includes a clock divider configured to adjust the second clock signal by a division factor k0, an integer greater than or equal to 2. The division factor k0 can for example be supplied by a user, via a dedicated interface.

In one embodiment, the subsampler (301, 400) includes a module for adapting the subsampling factor k1 to an adjustment of a frequency f_{B} of the second clock signal by the division factor k0. More generally, the adaptation module can adjust k0 according to any variation in frequency of the second clock signal, having regard to the number of flip-flops used. The following description indicates for example how to determine k1 according to the frequency of the second clock signal and the number of flip-flops.

In one embodiment, the subsampler includes a clock gating cell coupled to a counter of pulses in the input signal. The counter counts “k1” pulses to send an activation signal to the clock gating cell so that the latter allows the signal to pass as an input, as far as the following pulse.

In one embodiment, the set of flip-flops includes only two flip-flops in series. As described hereinafter, a greater number of flip-flops can be provided.

In one embodiment, when a required mean time between failures (MTBF) formula links a theoretical number N_{sync} of flip-flops to a first frequency f_{A} of the first clock signal and a second frequency f_{B} optionally adjusted) of the second clock signal: N_{sync}=function(f_{A},f_{B}), a subsampling factor k1 is fixed at a factor k2 selected from the N_{sync}−1 factors. A factor of N_{sync}−1 is included in the sense of multiplication: any integer (including 1 and N_{sync}−1) that can divide N_{sync}−1 (Euclidean division without remainder). The subsampling factor k1 is an integer greater than or equal to 2.

In this case, the number of flip-flops in series (in said set of flip-flops) is equal to (N_{sync}−1)/k2+1, in order to keep a constant duration of sampling of the input data. For example, if subsampling is implemented with a factor equal to N_{sync}−1, then only two flip-flops are necessary in series. If N_{sync}−1 is even and subsampling is implemented with a factor equal to N_{sync}−½, then three flip-flops are used in series. And so on.

A synchronization system is also proposed including:
a first synchronization unit as above between a first clock domain timed by a first clock signal and a second clock domain asynchronous with the first clock domain and timed by a second clock signal,
a second synchronization unit as above between a third clock domain timed by a third clock signal distinct from the first clock signal and the second clock domain asynchronous with the third clock domain,
wherein a shared subsampler supplies the same clock signal subsampling the second clock signal, to the flip-flops of the first and second synchronization units.

Naturally, the subsampler can time the flip-flops of a greater number of synchronization units between various original clock domains and the same second target clock domain asynchronous with these original clock domains.

If the reduction in the number of flip-flops in a synchronizer were to make it possible to compensate for adding the subsampler, pooling the latter with several original clock domains guarantees a real benefit in terms of surface area of silicon occupied and of electrical consumption attached to each synchronizer.

In one embodiment, a device includes a set of first flip-flops coupled in series, receiving first data in a first clock domain based on a first clock signal. The device includes a clock adjustment circuit including an input configured to receive a second clock signal asynchronous with the first clock signal, adjustment circuitry configured to generate an adjusted clock signal having a period larger than a period of the second clock signal, and an output coupled to a clock input of each of the flip-flops and configured to provide the adjusted clock signal to the clock input of each of the flip-flops. The set of first flip-flops are configured to output the first data in a second clock domain based on the second clock signal.

In one embodiment, a method is provided for synchronization between a first clock domain timed by a first clock signal and a second clock domain asynchronous with the first clock domain and timed by a second clock signal. The method includes obtaining at least one clock-division factor or clock-subsampling factor, adjusting, based on the clock-division factor, a variable frequency of the second clock signal at a target frequency to supply an adjusted clock signal timing the flip-flops, and controlling, with the adjusted clock signal, flip-flops put in series in a synchronization unit that receives as an input data of the first clock domain and supplies as an output data in the second clock domain.

In one embodiment, a method includes receiving, with a set of first flip-flops coupled in series, first input data in a first clock domain based on a first clock signal and receiving, with a clock adjustment circuit, a second clock signal asynchronous with the first clock signal. The method includes generating, with the clock adjustment circuit, an adjusted clock signal having a period larger than a period of the second clock signal, providing the adjusted clock signal to a clock input of each of the first flip-flops, and outputting the first input data from the set of first flip-flops in a second clock domain based on the second clock signal.

As set forth herein, the phrases “one embodiment,” “an embodiment,” and so forth do not limit subsequent features to a single embodiment, but rather the phrases indicate that such features are included in at least one embodiment.

### BRIEF DESCRIPTION OF THE SEVERAL VIEWS OF THE DRAWINGS

Other advantages and features of the disclosure will become apparent upon examining the detailed description of in no way limiting embodiments and implementations, and from the accompanying drawings, wherein:

FIG. 1 illustrates a synchronizer with flip-flops according to the prior art for synchronizing a data signal;

FIG. 2 illustrates a time diagram of the signals of the synchronizer of FIG. 1;

FIG. 3 illustrates a synchronization unit, according to an embodiment;

FIG. 4 illustrates an implementation of a subsampling unit, according to an embodiment;

FIG. 5 illustrates a time diagram of signals of a synchronizer, according to an embodiment;

FIG. 5A illustrates a time diagram of signals of a synchronizer, according to an embodiment;

FIG. 5B illustrates a time diagram of signals of a synchronizer, according to an embodiment;

FIG. 6 illustrates a synchronization system based on synchronizers with flip-flops, according to an embodiment; and

FIG. 7 illustrates, by a flow diagram, operations in an electronic system, according to an embodiment.

### DETAILED DESCRIPTION

In a context of clock-domain crossing, a synchronizer with flip-flops has a reduced number of flip-flops put in series, receiving as an input data of a first clock domain and supplying as an output data in the second clock domain. The second clock signal is at a variable frequency adjusted to a target frequency, by a division factor k0. The flip-flops are timed by a clock signal subsampling the second clock signal by a factor k1. The subsampled clock signal is generated by a frequency divider propagating a pulse of the signal every k1 clock pulses, while keeping the edges aligned. Theoretically additional flip-flops are avoided.

Electronic systems such as automobile systems can be implemented in the form of a system on chip (SoC), which is an integrated circuit including all the components of the system, often including, for example, components associated with different and asynchronous clock domains.

Clock domain crossing occurs when data are transferred from a flip-flop (a “source” flip-flop) controlled or timed by a first clock CLOCK_A to a flip-flop (a “destination” or “target” flip-flop) controlled by a second clock CLOCK_B.

Depending on the relationship between the clocks, problems may occur during the transfer of data between the source flip-flop and the target flip-flop. By way of example, if a transition at the output of the source flip-flop occurs very close to the active edge (rising or falling) of the second clock, a configuration or maintenance violation at the target flip-flop may occur. This may cause an oscillation of the output of the second flip-flop, which can become unstable and not stabilize at a stable value before the next active edge of the second clock. This condition is called metastability.

To reduce the uncertainty relating to the metastability of the target flip-flop, it is conventional to put several target flip-flops in series, making it possible to extend the sampling time for the data to several clock cycles, where the risks of metastability are almost zero.

The number N_{sync} of target flip-flops is generally obtained by the mean time between failures MTBF formula already mentioned above.

This number N_{sync} of flip-flops necessary for synchronizing the data in the second time domain increases rapidly with the frequency f_{B} of the second clock domain-condition sought to improve its performances-, but also with the use of lower-grade flip-flops-condition useful for reducing costs and having a simpler and less expensive design with the use of standard identical flip-flops.

A high number N_{sync} of flip-flops is prejudicial to the compactness of the synchronizer 100, as well as to the electrical consumption thereof.

Since electronic systems can include a large number of synchronization units between asynchronous clock domains, any additional flip-flop in these units leads to the same prejudice in terms of compactness and electrical consumption.

Adjusting a variable frequency of the second clock signal to a target frequency to supply a clock signal timing the flip-flops and/or using flip-flops controlled or timed by a clock signal subsampling the second target clock signal CLOCK_B makes it possible to reduce the number of flip-flops while keeping a constant sampling time for the input data, to keep the MTBF and therefore the risks of metastability unchanged. Thus, creating a virtual clock generating this adjusted and/or subsampled clock signal makes it possible to overcome the drawbacks of the known art.

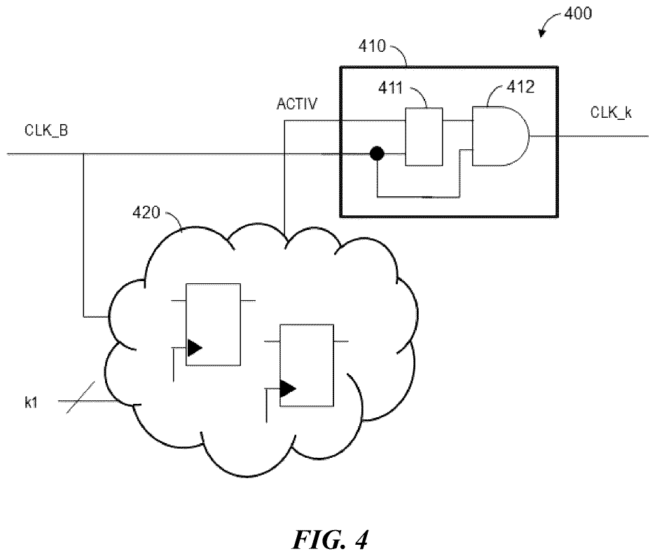

FIG. 3 illustrates a synchronization unit, or device, according to embodiments.

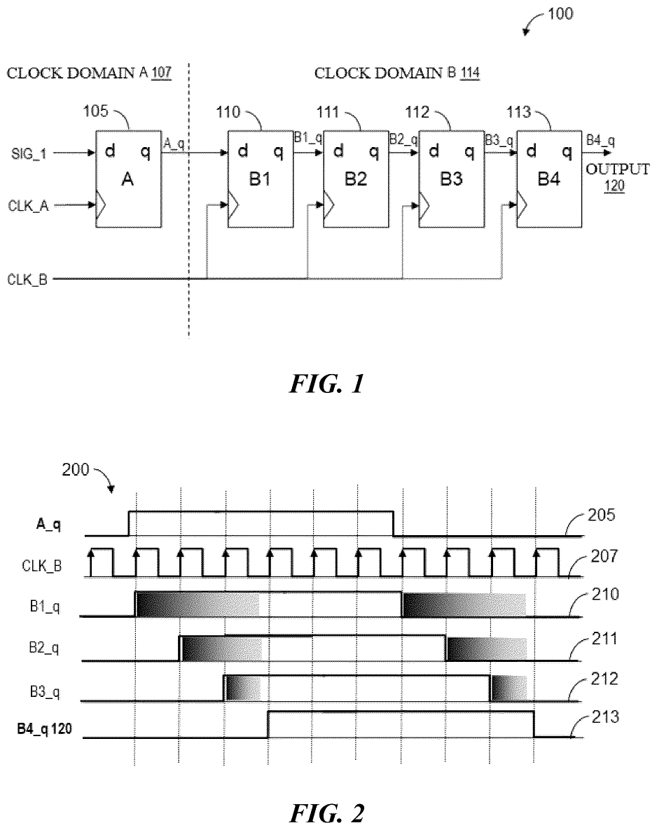

Solely for purposes of illustration, the two intermediate flip-flops 111, 112—henceforth superfluous—are shown in broken lines to illustrate how this synchronization unit improves the one in FIG. 1 discussed above.

The synchronizer with flip-flops 300 of FIG. 3 once again includes the flip-flop A 105 in the original clock domain A 107 and the set of flip-flops B in the target clock domain B 114.

The flip-flops are typically D flip-flops (standing for Data), i.e., including a single data input: “d,” the value of which is copied onto the output “q” at each clock edge (here rising edge, but in a variant this can be to the falling edge). The D flip-flop makes it possible to ensure a stable output state between two clock edges.

The set of flip-flops B includes two flip-flops B1 110 and B4 113 in series, timed by a clock CLK_k.

The clock CLK_k can be the second clock CLK_B adjusted to a target frequency, for example adapted to the number of flip-flops used. The target clock signal CLK_B can be generated by any known clock generator—and therefore not detailed here—such as an electronic oscillator (typically an RLC circuit). It is known that a variable-frequency clock source is provided with a clock divider 301 (dividing by an integer clock factor k0) making it possible to adjust downwards the clock frequency at the source output, with respect to a maximum operational frequency f_{Bmax}.

The clock CLK_k can be a virtual clock CLK_k that subsamples the target clock CLK_B, optionally previously adjusted by a clock factor k0. The virtual clock is implemented by the clock subsampling unit 301, which receives as an input the clock signal CLK_B (optionally adjusted by k0) and the subsampling parameter k1, an integer greater than or equal to 2. In the example in the figure, k=3, making it possible to divide by k=3 the clock frequency (e.g., rising edges) between the clock signal CLK_B (frequency: f_{B}) and the subsampled clock signal CLK_k (frequency: fₖ=f_{B}/k1).

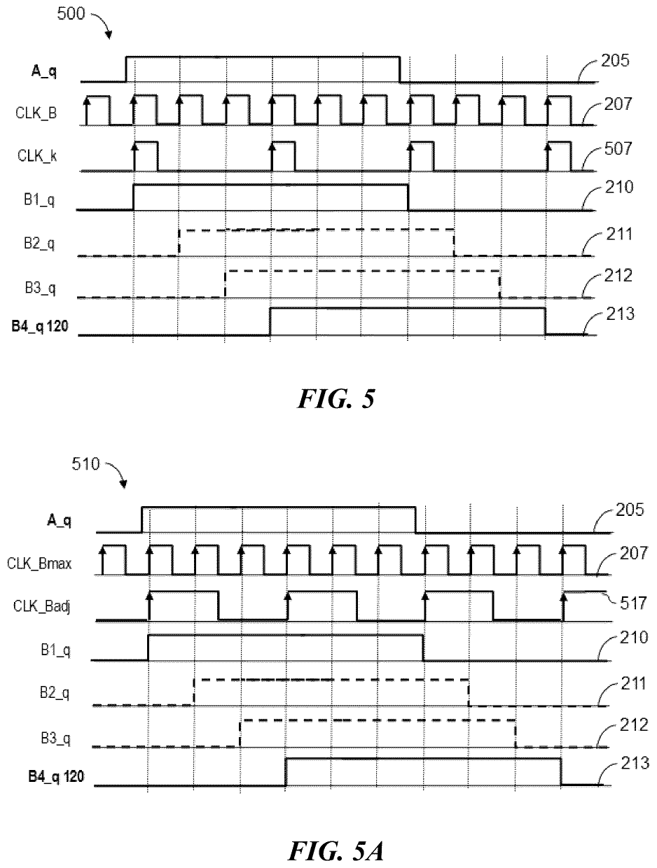

The parameter or parameters k0 and k1 can be pre-fixed in a register or a memory of the synchronizer 300. In a variant, they can be adjusted by a user through a user interface (not illustrated). In another variant, they can be dynamically adapted (by an adaptation module not shown on FIG. 4 below), for example the subsampling factor k1 can be adjusted to the variations in the frequency f_{B} of the target clock domain B by the division factor k0 (e.g., when the user modifies k0)

FIG. 4 illustrates an implementation of a subsampling unit 400. Any other implementation known to a person skilled in the art can be used.

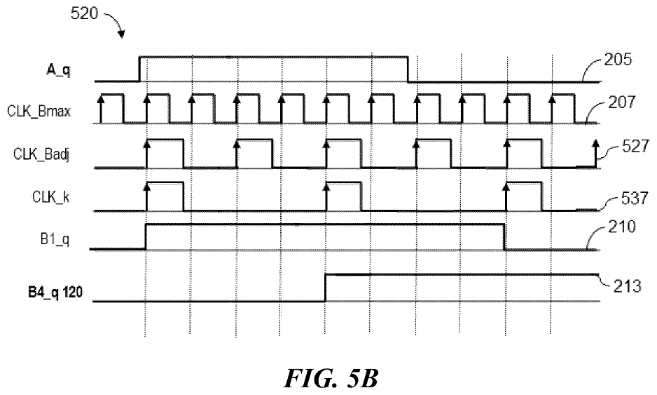

The subsampling unit makes it possible to generate the subsampled clock unit CLK_k by eliminating certain pulses of the clock signal CLK_B (or by copying the other pulses into a new signal). Thus the signals CLK_k and CLK_B remain in phase (their pulse edges are aligned, for the common pulses), as illustrated in FIG. 5.

The subsampling unit 400 shown includes a clock gating cell 410 coupled to a pulse counter 420 in the input signal, here CLK_B.

The pulse counter 420 is shown here highly schematically since there are numerous possible implementations, accessible to a person skilled in the art. The pulse counter 420 is configured to count the pulses of the input signal CLK_B, typically at each rising edge (or in a variant falling edge) and, according to the parameter k1, to generate a “high” or “strong” state of an activation signal ACTIV intended for the clock gating cell 410 whenever k1 pulses have been counted in the input signal CLK_B.

The clock gating cell 410 essentially stops the propagation of the clock signal CLK_B through it when an activation signal ACTIV at a “low” or “weak” level is applied to it. Only the pulses of the clock signal CLK_B during a high activation signal ACTIV are propagated to CLK_k.

For example, when k1=3, only one pulse out of three is propagated to the output CLK_k.

The clock gating cell 410 is of the latch-AND type, including a latch 411 and an AND gate 412. The latch 411 is controlled by the activation signal ACTIV to activate the AND gate 412 during a clock period, every k1 periods. The AND gate 412 therefore allows the clock signal CLK_B to propagate during one clock period every k periods, therefore allowing one pulse out of k1 to pass.

FIG. 5 illustrates a time diagram 500 of the signals of the synchronizer 301 or 400, with k1=3. The signals B2_q and B3_q of FIG. 1 are left visible (in broken lines) for any useful purpose whereas they no longer exist in the synchronizer.

Since the subsampler unit 400 allows one pulse out of three of the signal CLK_B to pass, the subsampled clock signal consists of one clock pulse every three clock cycles B, and therefore at a frequency f_{B}/3. The pulses of the signal CLK_k 507 are perfectly aligned in phase (in edges) with those of the initial signal CLK_B 207.

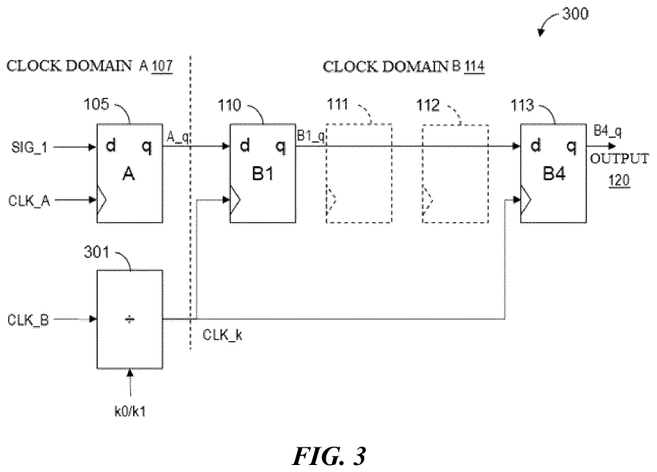

Since the flip-flops B are controlled by the signal CLK_k, the first flip-flop B1 takes the value of the data A_q at one pulse of the signal CLK_k, and the second flip-flop b4 in series takes the value of the data B1_q at the following pulse of the signal CLK_k. The second flip-flop B4 therefore does not operate at the clock cycle B following that of the first flip-flop B1, but at a following virtual clock cycle, and therefore after k1=3 clock cycles B. This guarantees keeping the sampling time unchanged: the flip-flop B4 of the synchronization unit 400 operates at the same instants as the flip-flop B4 of the synchronization unit 100 (FIG. 2).

Although the example in FIG. 3 illustrates two flip-flops B, the synchronization unit 400 can contain a larger number thereof, which is reduced compared with the theoretical number N_{sync} of flip-flops for the target frequency f_{B}.

Likewise, although the above example of FIG. 3 is described with a subsampling factor of 3, other values can be used.

The above mean time between failures (MTBF) formula links the theoretical number N_{sync} of flip-flops to the frequency f_{A} and the frequency f_{B}, but also to the required MTBF and to the characteristics of the flip-flops used. This number N_{sync} can be 3, 4, 5, 6, or even more. Though the known techniques impose hardware implementations providing for this exact number (or more) of flip-flops, the approach described above makes it possible to reduce the number thereof.

It makes it possible in particular to use lower-grade flip-flops (for example conventional flip-flops) without increasing (or even by reducing) the number of flip-flops actually used. The approach described above therefore offers broadened access to the catalogue of flip-flops available without impact on the performance of the synchronization unit.

It also makes it possible to improve the performances of the target clock domain B—via increasing its operational frequency f_{B}—without increasing (or even by reducing) the number of flip-flops actually use.

Typically, the number N_{sync}−1 obtained according to the constraints involved (required MTBF, f_{A}, f_{B}, characteristics of the flip-flops used) has two or more factors, in the sense of multiplication, namely at least 1 and N_{sync}−1, and optionally any integer divider of N_{sync}−1. Any factor k2 among these two or more factors can be selected as subsampling factor k1.

For example, for N_{sync}=5, the following factors are available: 1, 2, 4; for N_{sync}=6:1, and 5; for N_{sync}=7:1, 2, 3, 6; etc.

The choice of the factor k2 can depend on the number of flip-flops to be used, and/or possibilities offered by the subsampling unit 301, 400.

The number N_{B} of flip-flops B is in fact related to the factor k2 selected by the following formula, to keep a constant sampling time for the input data: N_{B}=(N_{sync}−1)/k2+1.

Thus, if k2=N_{sync}−1, then only two flip-flops B are necessary instead of N_{sync}. This is the case in FIG. 3, where there is a change from four (N_{sync}=4) flip-flops B (see FIG. 1) to only two while dividing the flip-flop control frequency by 3 (N_{sync}−1).

By way of illustration, if N_{sync}=5 and k2=2, then three flip-flops B can be used instead of five; if N_{sync}=7 and k2=2, then four flip-flops are necessary whereas with k2=3 three flip-flops B can be used instead of seven.

Although it is envisaged above remaining at equal sampling times for the input data, it is however possible to use the above teachings to reduce the number of flip-flops, even while extending the time for sampling the input data.

For example, if a subsampling unit 301, 400 is already available with a subsampling factor k1 that is not compatible with the theoretical number N_{sync} of flip-flops B (k1 does not divide N_{sync}−1), then it is possible to use a higher theoretical N_{sync}′ that satisfies the condition: k1 divides N_{sync}′−1. The extension of the sampling time is then equal to (N_{sync}′−N_{sync})/f_{B}.

By way of illustration, if N_{sync}−5 and the subsampling unit divides f_{B} by 3, then N_{sync}′ can be fixed at 7. Three flip-flops B will then be used instead of the 5 (N_{sync}). On the other hand, the sampling time will change from 5/f_{B} to 7/f_{B}.

Finally, there are scenarios where the frequency f_{B} is adjusted (e.g., by a user) by a division factor k0 to slow down (or accelerate) the clock over time, whereas the synchronization unit 301, 400 is in operation (and therefore the number of flip-flops B is fixed as above). In this case, the subsampling unit 301, 400 can be provided with a module for dynamic (and therefore automatic) adaptation of the subsampling factor k1 to the variations in f_{B} by the division factor k0.

As indicated above, the unit 301 of FIG. 3 symbolizes a clock divider when the frequency f_{B} of the second clock CLK_B is adjusted to a target frequency by the division factor k0, but also a unit for subsampling the target clock CLK_B by the clock factor k0. When the two operations (adjustments and subsampling) are implemented in a combined manner, a clock divider is provided in the clock source CLK_B and a distinct subsampler is provided in front of the signal CLK_B.

Thus, in embodiments, the subsampling unit 400 of FIG. 4 can be replaced (or supplemented) by a clock divider known to a person skilled in the art.

FIG. 5A illustrates a time diagram 510 of the signals of the synchronizer 301 or 400, with k0=3, without subsampling of CLK_B. The signals B2_q and B3_q of FIG. 1 are left visible (in broken lines) for any useful purpose whereas they no longer exist in the synchronizer.

Adjusting the frequency f_{B} of the clock CLK_B by k0-3 makes it possible to multiply the clock period by k0. The pulses of the signal CLK_Badj 517 are perfectly aligned in phase (in edges) with those of the initial signal CLK_Bmax 207 corresponding to the maximum clock frequency of the domain B, f_{Bmax}.

Since the flip-flops B are controlled by the adjusted signal CLK_Badj, the first flip-flop B1 takes the value of the data A_q at one pulse of the signal CLK_Badj, and the second flip-flop b4 in series takes the value of the data B1_q at the following pulse of the signal CLK_Badj, i.e., at the end of a period corresponding to three periods of the maximum frequency f_{Bmax} of CLK_Bmax.

A person skilled in the art thus understands that it is possible to combine the mechanisms for adjusting the frequency f_{B} of the clock signal CLK_B by k0 and of subsampling the clock frequency CLK_B by k1 in order to obtain a period T between two edges of CLK_k best adjusted: T=(k0·k1)/f_{Bmax}.

FIG. 5B illustrates for example a time diagram 520 of the signal CLK_k, with k0=2 and k1=2. The adjusted signal CLK_Badj 527 has a rising edge every k0=2 rising edges of the signal CLK_Bmax. The signal CLK_k 537 thus has a rising edge every k·k1=4 rising edges of the signal CLK_Bmax.

Typically, k0 and k1 can be selected so that k0·k1 is a factor of (N_{sync}−1)/(N_{B}−1), N_{sync} being determined using the maximum frequency f_{Bmax}.

In a variant, if a user fixes k0, the adjusted frequency f_{B} is f_{Bmax}/k0. k1 can then be selected so that k1 is a factor of (N_{sync}−1)/(N_{B}−1), N_{sync} being determined using the adjusted frequency f_{B}.

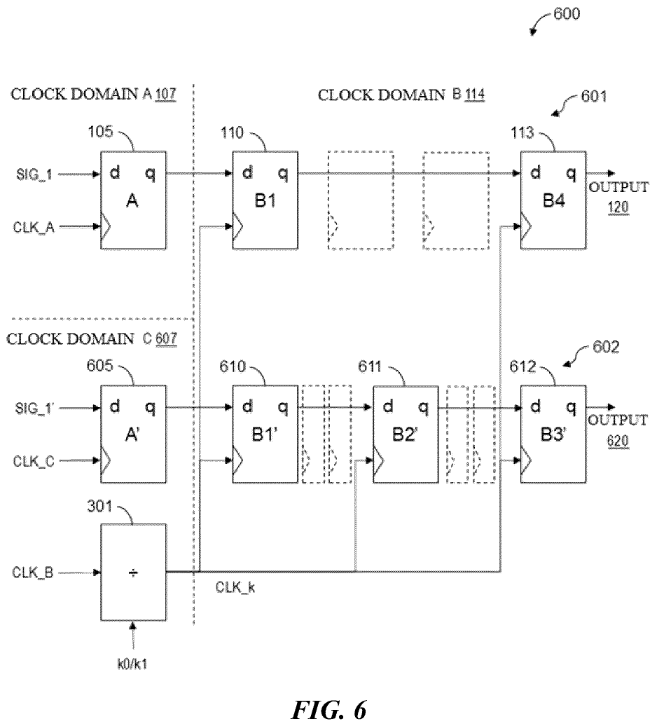

FIG. 6 illustrates a synchronization system 600 based on synchronizers with flip-flop. This synchronization system can form part of a more complex electronic system in which three or more clock domains cohabit. To simplify the explanations, reference is made to three clock domains only, which are asynchronous: A 107, B 114 and C 607. Naturally, another number of clock domains can be used that repeats the teachings of the present disclosure.

Data of the clock domains A 107 and C 607 are transmitted to the clock domain B asynchronous with A and C, requiring respective clock-domain crossings: A to B and C to B.

If the synchronization unit 601 between the domains A and B is, for the example, identical to that of FIG. 3, the one 602 between domains C and can B includes three flip-flops B in series receiving the data from the flip-flop A′ 605 of the domain C and supplying the output SORTIE 620: B1′ 610, B2′ 611 and B3′ 612. This is however only one example; the number of flip-flops B in the synchronization unit 602 can be the same as the number in the synchronization unit 601, or may be greater.

The flip-flops in broken lines in the synchronization unit 602 are not used. They illustrate, for any useful purpose, the flip-flops theoretically necessary when N_{sync}=7 for the crossing of the clock domain C to B.

The flip-flops of the synchronization unit 602 can be identical (of the same nature) to those of the synchronization unit 601, or be different.

The flip-flops of the synchronization unit 601 and those of the synchronization unit 602 are all controlled by the same subsampled signal CLK_k coming from the clock subsampling unit 301. The latter is therefore shared between several clock-domain crossings to one and the same target clock domain (here B), and therefore shared between several source clock domains (here A and C).

The costs (integrated-circuit surface, electrical consumption) of the subsampler unit 301 are thus more reduced by the synchronization unit, the more clock-domain crossings there are to be implemented to the same clock domain.

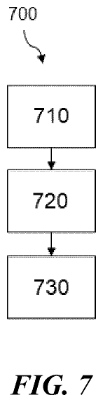

FIG. 7 illustrates, by a flow diagram, operations 700 in an electronic system having at least one clock-domain crossing, i.e., an electronic system with a plurality of asynchronous clock domains that exchange data.

The operations 700 begin at the step 710 with the recovery of the clock-subsampling factor k.

In one embodiment, k0 and/or k1 are stored in memory or in a register internal to the electronic system.

In another embodiment, k0 and/or k1 are entered by a user when the electronic system is initiated.

In yet another embodiment, k0 and/or K1 are determined by the electronic system from a synchronization-unit configuration 300, 601, 602. Typically, on the one hand, first information such as the frequencies f_{A}, f_{B}, fc (for the domain C), the mean time between failures MTBF and the characteristics of the flip-flops Be used are known and, on the other hand, second information such as the number N_{B} of flip-flops B available in the synchronization unit 300, 601, 602 (for example 2) are known. The electronic system can therefore determine the division factor or factors k0 and clock-subsampling factor or factors k1, by calculating first of all N_{sync} with the first information and then determining k2=(N_{sync}−1)/(N_{B}−1). If k2 is an integer, k0=k2 or k1=k2 or k0·k1=k2. Otherwise a higher integer can be selected for k0 and/or k1, preferably the integer immediately higher: k0 or k1 or k0·k1=higher integer part (k2).

At the step 720, the clock divider or the clock-subsampling unit 301, 400 is started with the clock factor k0 or clock-subsampling factor k1 respectively, as determined at the step 710.

For example, in the case of subsampling, the subsampling unit 301, 400 propagates one clock pulse of the signal CLK_B over k1 pulses. This forms the subsampled clock signal CLK_k. Thus a clock signal CLK_k subsampling the clock signal CLK_B is generated.

At the step 730, the subsampled clock signal CLK_k is supplied to the flip-flops B of the synchronization unit 300, 601, 602 in order to control them at a frequency f_{B}/k1.

This control makes it possible to transfer the data from the source clock domain or domains to the target clock domain B, in a synchronized manner, while maintaining a required mean time between failures.

Of course, the present disclosure is not limited to the embodiments described above by way of example; it extends to other variants. Other embodiments are possible.

In one embodiment, a unit (300, 601, 602) for synchronizing between a first clock domain (107, 607) timed by a first clock signal (CLK_A, CLK_C) and a second clock domain (114) asynchronous with the first clock domain and timed by a second clock signal (CLK_B), the synchronization unit including: a set of flip-flops (110, 113, 610, 611, 612) put in series, receiving as an input data (A_q) of the first clock domain and supplying as an output (120, 620) data in the second clock domain, wherein the second clock signal (CLK_B) is at a variable frequency adjusted to a target frequency (f_{B}) to supply a clock signal timing the flip-flops (110, 113, 610, 611, 612) and/or the flip-flops (110, 113, 610, 611, 612) are timed by a clock signal (CLK_k) subsampling the second clock signal (CLK_B).

In one embodiment, the synchronization unit (300, 601, 602) including a subsampler (301, 400) configured to subsample an input signal by a subsampling factor (k1), an integer greater than or equal to 2, the subsampler receiving, as input signal, the second clock signal (CLK_B).

In one embodiment, a source of the second clock signal includes a clock divider (301, 400) configured to adjust the second clock signal by a division factor (k0), an integer greater than or equal to 2.

In one embodiment, the subsampler (301, 400) includes a module for adapting the subsampling factor (k1) to an adjustment of a frequency (f_{B}) of the second clock signal (CLK_B) by the division factor (k0).

In one embodiment, the subsampler (301, 400) includes a clock gating cell (410) coupled to a counter (420) of pulses in the input signal.

In one embodiment, the set of flip-flops includes only two flip-flops in series (110, 113).

In one embodiment, when a required mean time between failures (MTBF) formula links a theoretical number N_{sync} of flip-flops to a first frequency (f_{A}) of the first clock signal (CLK_A) and a second frequency (f_{B}) of the second clock signal (CLK_B), a subsampling factor k is fixed at a factor k2 selected from the factors of N_{sync}−1.

In one embodiment, a system (600) includes a first synchronization unit (601) between a first clock domain (107) timed by a first clock signal (CLK_A, CLK_C) and a second clock domain (114) asynchronous with the first clock domain and timed by a second clock signal (CLK_B), a second synchronization unit (602) between a third clock domain (607) timed by a third clock signal (CLK_C) distinct from the first clock signal (CLK_A) and the second clock domain (114) asynchronous with the third clock domain (607), wherein a shared subsampler (301, 400) supplies the same clock signal (CLK_k) subsampling the second clock signal (CLK_B), to the flip-flops (110, 113, 610, 611, 612) of the first and second synchronization units (601, 602).

In one embodiment, one embodiment for synchronization between a first clock domain (107, 607) timed by a first clock signal (CLK_A, CLK_C) and a second clock domain (114) asynchronous with the first clock domain and timed by a second clock signal (CLK_B), the method including the following steps: obtaining (710) at least one clock-division factor (k0) or clock-subsampling factor (k1), adjusting, by the clock-division factor, a variable frequency of the second clock signal at a target frequency to supply a clock signal timing the flip-flops and/or generating (720), by the clock-subsampling factor obtained, a clock signal (CLK_k) subsampling the second clock signal (CLK_B), and controlling (730), with the adjusted and/or generated clock signal (CLK_k), flip-flops (110, 113, 610, 611, 612) put in series in a synchronization unit (300, 601, 602) that receives as an input data (A_q) of the first clock domain and supplies as an output (120, 620) data in the second clock domain.

In one embodiment, a system includes a synchronization unit (300, 601, 602).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a set of first flip-flops coupled in series, receiving first data in a first clock domain based on a first clock signal; and
a clock adjustment circuit including:
an input configured to receive a second clock signal asynchronous with the first clock signal;
adjustment circuitry configured to generate an adjusted clock signal having a period larger than a period of the second clock signal; and
an output coupled to a clock input of each of the flip-flops and configured to provide the adjusted clock signal to the clock input of each of the first flip-flops, wherein the set of first flip-flops is configured to output the first data in a second clock domain asynchronous with the first clock domain and based on the second clock signal.

2. The device according to claim 1, wherein the adjustment circuitry includes a subsampler configured to subsample the second clock signal by a subsampling factor, an integer greater than or equal to 2, the subsampler receiving, as input signal, the second clock signal and outputting the adjusted clock signal.

3. The circuit according to claim 2, wherein the adjustment circuit includes a clock divider upstream from the subsampler and configured to adjust the second clock signal by a division factor corresponding to an integer greater than or equal to 2.

4. The device according to claim 3, wherein the subsampler includes a module for adapting the subsampling factor to an adjustment of a frequency of the second clock signal by the division factor.

5. The device according to claim 2, wherein the subsampler comprises a counter configured to count pulses of the second clock signal and a clock gating cell coupled to the counter.

6. The device according to claim 1, wherein the set of flip-flops includes only two flip-flops in series.

7. The device according to claim 1, wherein, when a mean time between failures formula links a theoretical number N_{sync} of flip-flops to a first frequency of the first clock signal and a second frequency of the second clock signal, a subsampling factor k is fixed at a factor k2 selected from the factors of N_{sync}−1.

8. The device according to claim 1, wherein the adjustment circuit includes a clock divider configured to generate the adjusted clock signal by dividing the second clock signal by a division factor corresponding to an integer greater than or equal to 2.

9. The device according to claim 1, comprising a set of second flip-flops coupled in series and receiving second data in a third clock domain based on a third clock signal and each having a clock input coupled to receive the adjusted clock signal from the clock adjustment circuit, wherein the clock adjustment causes the second flip-flops to output the second data in the second clock domain, the third clock domain being asynchronous with the second clock domain.

10. A method for synchronization between a first clock domain timed by a first clock signal and a second clock domain asynchronous with the first clock domain and timed by a second clock signal, the method comprising:
obtaining at least one clock-division factor or clock-subsampling factor;
adjusting, based on the clock-division factor, a variable frequency of the second clock signal at a target frequency to supply an adjusted clock signal timing the flip-flops; and
controlling, with the adjusted clock signal, flip-flops put in series in a synchronization unit that receives as an input data of the first clock domain and supplies as an output data in the second clock domain.

11. The method of claim 10, wherein adjusting the variable frequency includes generating the adjusted clock signal by dividing the second clock signal with a frequency divider.

12. The method of claim 10, wherein adjusting the variable frequency includes generating the adjusted clock signal by subsampling the second clock signal with a subsampler.

13. The method of claim 10, wherein adjusting the variable frequency includes generating the adjusted clock signal by dividing a frequency of the second clock signal with a frequency divider and subsampling the output of the frequency divider with a subsampler.

14. A method, comprising receiving, with a set of first flip-flops coupled in series, first input data in a first clock domain based on a first clock signal;
receiving, with a clock adjustment circuit, a second clock signal asynchronous with the first clock signal;
generating, with the clock adjustment circuit, an adjusted clock signal having a period larger than a period of the second clock signal; and
providing the adjusted clock signal to a clock input of each of the first flip-flops; and
outputting the first input data from the set of first flip-flops in a second clock domain based on the second clock signal.

15. The method of claim 14, wherein generating the adjusted clock signal includes dividing the second clock signal with a frequency divider of the frequency adjustment circuit.

16. The method of claim 14, wherein generating variable frequency includes subsampling the second clock signal with a subsampler of the clock adjustment circuit.

17. The method of claim 16, wherein the subsampler includes a counter configured to count pulses of the second clock signal and a clock gating cell coupled to the counter.

18. The method of claim 14, wherein the set of first flip-flops includes only two first flip-flops in series.

19. The method of claim 14, wherein generating the variable frequency includes generating a divided clock signal by dividing the frequency of the second clock signal with a frequency divider and subsampling the output of the frequency divider with a subsampler.

20. The method of claim 11, further comprising:
receiving, with a set of second flip-flops coupled in series, second data in a third clock domain based on a third clock signal;
providing the adjusted clock signal to a clock input of each of the second flip-flops; and
outputting the second data from the set of second flip-flops in the second clock domain, the second clock domain being asynchronous with the first clock domain.
